(19) United States
(12) Patent Application Publication
(10) Pub. No.: US 2015/0044110 A1
(43) Pub. Date: Feb. 12, 2015

(54) MICROFLUIDIC DEVICE WITH HYDROPHOBIC SURFACE MODIFICATION LAYER AND MANUFACTURING METHOD THEREOF

(71) Applicant: STMicroelectronics S.r.l., Agrate Brianza (IT)

(72) Inventors: Lorenzo Colombo, Besana In Brianza (IT); Marco Salina, Cremosano (IT); Daria Doria, Como (IT)

(73) Assignee: STMicroelectronics S.r.l., Agrate Brianza (IT)

(21) Appl. No.: 14/451,805

(22) Filed: Aug. 5, 2014

(30) Foreign Application Priority Data
Aug. 7, 2013 (IT) TO2013A000680

(51) Int. Cl. B01L 3/00; B32B 37/18; G03F 7/20; B05D 3/06; B32B 38/00; B32B 37/24; B05D 1/00; B05D 3/10

(52) U.S. Cl. CPC B01L 3/5027; B05D 1/005; B32B 37/18; B05D 3/107; B05D 3/06; B32B 38/00; B32B 37/24; G03F 7/20; B32B 2038/0076; B32B 2037/243; B32B 2255/00; B32B 2307/728; B32B 2310/0806; B01L 2300/12
USPC 422/502; 427/2.11; 156/275.5; 216/95; 430/320

(57) ABSTRACT

A microfluidic device includes a support body having a first surface and a second surface opposite to one another. The first surface is hydrophilic. A surface modification layer extends over the first surface of the support body. At least one opening is formed to extend through the surface modification layer and expose a portion of the first surface. The surface modification layer is hydrophobic. In particular, the surface modification layer is made of a photodefinible material chosen from among: an epoxy resin, a polyamide, and a photocurable siloxane-based polymer. The openings are functionalized using probe molecules designed to bind with specific target molecules to be detected.

### PRIORITY CLAIM

This application claims priority from Italian Application for Patent No. TO2013A000680 filed Aug. 7, 2013, the disclosure of which is incorporated by reference.

### TECHNICAL FIELD

The present invention relates to a microfluidic device with hydrophobic surface modification layer and to a method for manufacture thereof.

### BACKGROUND

In the prior art there has been felt the need to control the wettability of surfaces, for example for confinement of liquids by exploiting the principle of surface tension.

Known methods for confinement of liquids include providing a hydrophobic substrate (having low wettability) and laying drops of liquid on the hydrophobic substrate at a distance from one another, in respective locations of the hydrophobic substrate. The drops thus arranged present an angle of contact with the substrate that is typically greater than 90° on account of the hydrophobicity of the substrate itself and due to phenomena of surface tension of the liquid drops, each of which remains in a respective position, without mixing with one another.

However, this embodiment presents some drawbacks, above all in the presence of organic molecules within the liquid deposited. In fact, it is known that molecules, typically organic ones, can form by adsorption a chemical bond or set up an interaction of a chemico-physical type, through Van der Waals forces, with a hydrophobic surface (also known as hydrophobic bond).

This effect renders unfavorable development of analysis devices of a Lab-on-Chip (LOC) type, in which the chemical and biological reactions take place in small amounts of liquid deposited on the hydrophobic surface. To overcome these drawbacks, a microfluidic chip for biological analyses is typically configured for housing a liquid for being analyzed in chambers or wells dug in a hydrophilic substrate, thus forming reaction chambers in which the chemico-physical interactions of adsorption towards a hydrophobic surface (hydrophobic bonds) are reduced.

There is a need in the art to provide a microfluidic device with hydrophobic surface modification layer, and a method for manufacture thereof, that will be able to overcome the drawbacks of the prior art.

### SUMMARY

According to embodiments, a microfluidic device with hydrophobic surface modification layer and a method for manufacture thereof are provided.

In an embodiment, a microfluidic device comprises: a support body having a first surface and a second surface opposite to one another, wherein the first surface is hydrophilic; a hydrophobic surface modification layer extending over the first surface of the support body, wherein the surface modification layer has at least one opening extending completely through the surface modification layer, thus exposing a portion of the first surface, and wherein the surface modification layer is made of a photodefinible material selected from the group consisting of: an epoxy resin, a polyamide, and a photocurable siloxane-based polymer; and at least one sensing region housed in each opening comprising one or more receptors which are configured to bond with respective one or more binding mates.

In an embodiment, a method for manufacturing a microfluidic device comprises: forming a hydrophobic surface modification layer on a first surface of a support body having said first surface and a second surface opposite thereto, wherein the first surface is hydrophilic, wherein the surface modification layer is made of a photodefinible material selected from the group consisting of: an epoxy resin, a polyamide, and a photocurable siloxane-based polymer; forming at least one opening through the surface modification layer to expose a portion of the first surface; and functionalizing said portion of the first surface to form at least one sensing region comprising one or more receptors which are configured to bond with respective one or more binding mates.

### BRIEF DESCRIPTION OF THE CLAIMS

For a better understanding of the present invention, preferred embodiments thereof are now described, purely by way of non-limiting example and with reference to the attached drawings, wherein:

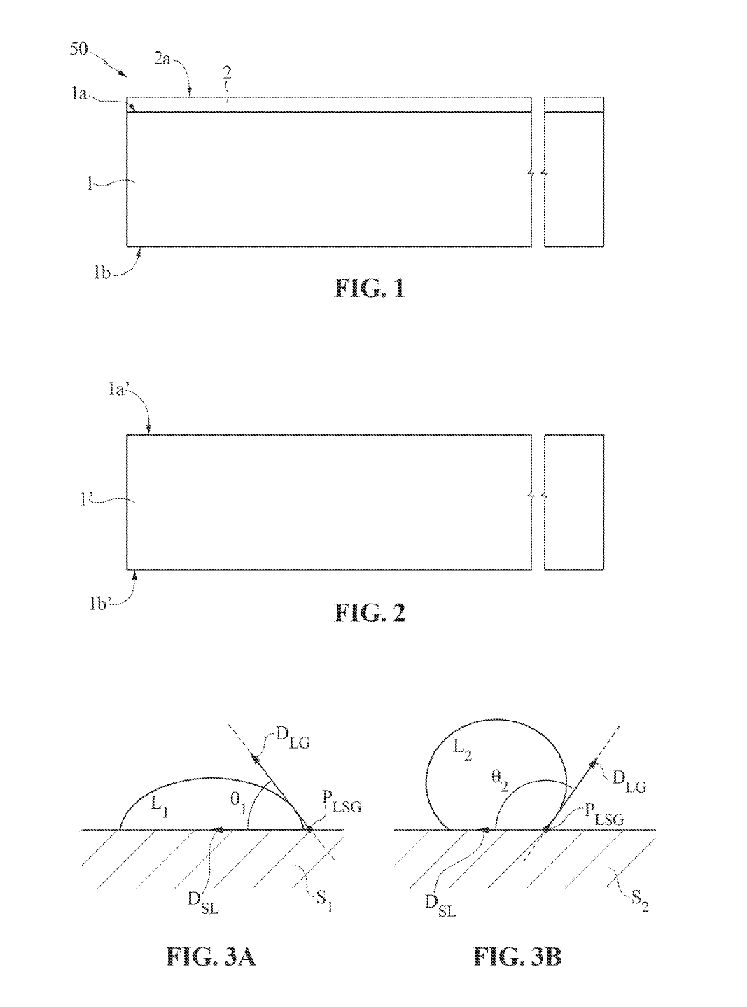

FIG. 1 illustrates, in cross-sectional view, a wafer in an intermediate manufacturing step, according to one embodiment;

FIG. 2 illustrates, in cross-sectional view, a wafer in an intermediate manufacturing step, according to an embodiment alternative to that of FIG. 1;

FIGS. 3A and 3B show, in cross-sectional view, drops of a liquid arranged on a hydrophilic surface and a hydrophobic surface, respectively;

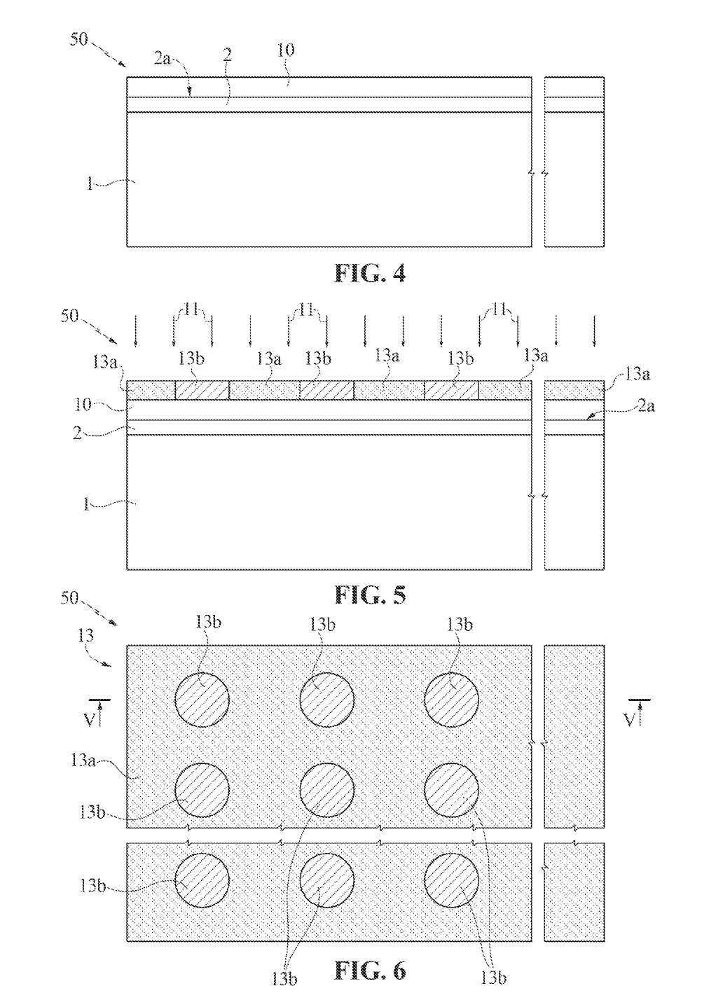

FIGS. 4-7 show, in cross-sectional view, further manufacturing steps for producing the wafer of FIG. 1, according to one embodiment;

FIG. 8 shows a chemical microreactor manufactured as described with reference to FIGS. 1 and 4-7; and

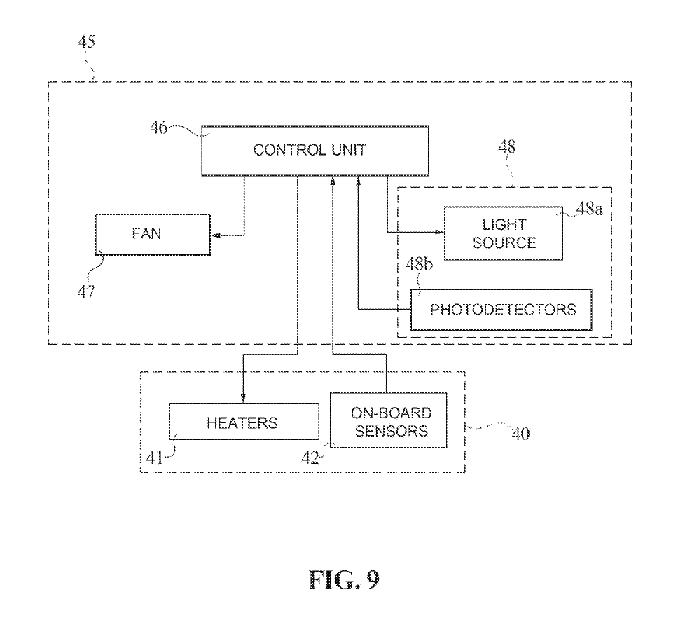

FIG. 9 shows a diagnostic system comprising the chemical microreactor of FIG. 8.

### DETAILED DESCRIPTION OF THE DRAWINGS

With reference to FIG. 1, a wafer 50 is provided including a substrate 1 having a hydrophilic surface.

According to one embodiment, the substrate 1 is made of semiconductor material, in particular silicon, and houses, on a first side 1a thereof, a structural layer 2 made, for example, of silicon oxide (SiO₂) deposited using the CVD (chemical vapor deposition) technique or grown thermally, designed to modify the properties of wettability of the substrate 1. In this case, the structural layer 2 is made of a hydrophilic material and is designed to expose a hydrophilic surface 2a thereof.

According to a further embodiment (FIG. 2), a substrate 1′ is itself made of hydrophilic material, e.g., silicon oxide (SiO₂), and exposes the hydrophilic surface 1a′ without any need for intermediate layers designed to modify the properties of wettability of the substrate 1′.

It is evident that, according to further embodiments, the substrate 1, 1′ and the structural layer 2 (when present) may be made of materials different from the ones mentioned, provided that the surface 1a′, or the surface 2a of the structural layer 2, shows hydrophilic properties. For instance, the substrate 1′ or the layer 2 may be made of silicon oxide, silicon carbide (SiC), of silicon nitride (SiN), silicon, or other hydrophilic materials.

In the context of this disclosure, considered as hydrophobic is a surface having reduced wettability, i.e., such that the surface interaction between a liquid (e.g., water) and the surface itself is minimal. Said interaction can be assessed in terms of angle of contact of a drop of water deposited on the surface considered, measured as angle formed at the surface-liquid interface. A reduced angle of contact is due to the tendency of the drop to flatten on the surface, and vice versa. FIG. 3A shows a drop of water L₁ set on a hydrophilic surface S₁. In this case, the drop L₁ presents an angle of contact θ=θ₁ with the surface S₁ of less than 90°. In general, considered as hydrophilic is a surface having characteristics of wettability such that, when a drop is deposited thereon, the angle of contact between the surface and the drop (angle θ) has a value of less than 90°, in particular equal to or less than approximately 40°.

FIG. 3B shows a drop of water L₂ set on a hydrophobic surface S₂. In this case, the angle of contact θ=θ₂ is greater than 90°. Considered as hydrophobic is a surface having characteristics of wettability such that, when a drop is deposited thereon, the angle of contact between the surface and the drop (angle θ) has a value greater than 90°.

The angle of contact θ is, as is known, a thermodynamic quantity, the theoretical treatment of which is based upon the thermodynamic equilibrium between three phases: liquid phase of the drop, solid phase of the surface (e.g., the substrate) considered, and gaseous phase of the surrounding environment (mixture between the environmental atmosphere and an equilibrium concentration of the substance of the drop in the vapor phase). The angle of contact θ is defined by the angle formed by the encounter of the solid-gas interface (also referred to as solid-vapor interface) with the solid-liquid interface. This quantity is defined for an ideal surface, i.e., a smooth and homogeneous surface, by the following Young's relation:

γ_{SG}−γ_{SL}−γ_{LG}·cos θ=0

where γ_{SG} is the tension of the solid-gas interface, γ_{SL} is the tension of the solid-liquid interface, and γ_{LG} is the tension of the liquid-gas interface.

Ideally, one has complete wettability when γ_{SG}>γ_{SL}+γ_{LG}, i.e., cos θ>1, and zero wettability when γ_{SL}>γ_{SG}+γ_{LG}, i.e., cos θ<(−1).

Hence, considering a cross section of a drop of liquid deposited on a solid surface (FIGS. 3A and 3B), the respective angle of contact θ is the angle comprised between the direction D_{SL} of the solid-liquid tension and the direction D_{LG} of the liquid-gas tension, tangential to the outer surface of the drop, with the vertex in the three-phase liquid-solid-gas point P_{LSG}. The angle of contact θ, in other words, corresponds to the thermodynamic quantity that minimizes the surface free energy of the system and is physically described by Young's law, which corresponds to the balance of the horizontal forces acting on a drop (of negligible volume) deposited on an ideal surface.

To return to the manufacturing method, after the step of FIG. 1 or FIG. 2, according to the respective embodiments, the next step is that of FIG. 4. FIG. 4 shows a substrate 1 provided with the structural layer 2 according to the embodiment of FIG. 1. However, what has been described herein may be applied in a similar way to the embodiment of FIG. 2.

Hence, on the surface 2a a surface modification layer 10 is formed, of a material having hydrophobic characteristics, i.e., such that a drop of liquid (e.g., water) deposited thereon shows an angle of contact θ greater than 90°. Preferably, the angle of contact is greater than 100°, for example 106°. The surface modification layer 10 has a freely chosen thickness, for example comprised between 1 μm and 100 μm. The surface modification layer 10 is formed, according to one embodiment, starting from a polymer in liquid form, deposited on the structural layer 2 by means of the spin-coating technique and solidified by means of an appropriate curing step. The polymer used, after the curing step, has, as has been said, hydrophobic characteristics and is permanent.

Alternatively, according to a different embodiment, the surface modification layer 10 is formed by means of a technique of lamination of a permanent dry film having hydrophobic characteristics.

In general, the surface modification layer 10 is made of a photodefinible (photocurable) material with permanent and preferably biocompatible hydrophobic characteristics.

According to one embodiment, the surface modification layer 10 is made of a photosensitive epoxy resin (available either in liquid form or in solid form of dry film), having hydrophobic characteristics (i.e., such as to present a final angle of contact after the curing step greater than 90°, preferably greater than 100°). Alternatively, the surface modification layer 10 is made of polyamide.

Epoxy resins comprise, for example, SU8, TOK TMMF, TOK TMMR, etc.

Polyamides comprise, for example, HD PI26XX, HD88XX, HD89XX, FFEM AP22XX, etc.

According to a further embodiment, the surface modification layer 10 is made of a siloxane-based material. Even more in particular, the material used is known by the trade name “SINR” and is produced by Shin-Etsu MicroSi. This material is formed by a linear chain with a siloxane base and has a component that renders it sensitive to ultraviolet light, which triggers a cross-linking process, as is commonly known for the photoresists.

Reference is made to U.S. Pat. No. 6,590,010 (incorporated by reference) which describes a photocurable siloxane-based polymer designed for being used for formation of the surface modification layer 10. Said polymer has a recurrent unit according to formula (I) and has a molecular weight between 500 and 200 000:

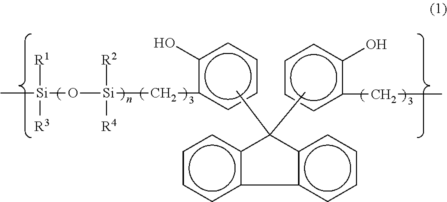

where R¹ and R⁴ are each a C₁-C₈ alkyl, for example CH₃, and n is an integer between 1 and 1000.

It has been found that a surface modification layer 10 of the material according to formula (I) shows an angle of contact θ greater than 105°, is permanent in so far as it is fully cross-linked after the final curing treatment and resistant to acids and solvents; moreover, it is biocompatible.

In the sequel of the present description, it is assumed that the surface modification layer is the polymer according to formula (1), in particular in the form of a dry film.

In this case, there follows lamination of the dry film on the wafer 50, which is brought to a temperature of between 50° C. and 120° C., in particular 70° C., for a time comprised between 30 s and 300 s, in particular 60 s. The surface modification layer 10 is thus formed.

Then (FIG. 5), a step of exposure of the wafer 50 to ultraviolet radiation (arrows 11) is carried out using an exposure mask 13. For instance, using the material according to formula (I) as material for the surface modification layer 10, the ultraviolet radiation used for exposure has a wavelength comprised in the 365 to 436-nm range.

The exposure mask 13 is shown in top plan view in FIG. 6. FIG. 5 is a cross-sectional view of the representation of FIG. 6, taken along the line of cross section VI-VI. As may be noted, the exposure mask 13 includes regions 13a (dotted) that are transparent to the ultraviolet radiation 11 used and regions 13b (hatched) that are opaque to the ultraviolet radiation 11 used.

The exposure mask 13 is configured for blocking exposure to the ultraviolet radiation 11 of regions of the surface modification layer 10 extending substantially underneath the opaque regions 13b, whereas the regions of the surface modification layer 10 extending underneath the transparent regions 13a receive the ultraviolet radiation 11. The regions of the surface modification layer 10 extending underneath the opaque regions 13b are the regions in which it is desired to confine drops of liquid, as illustrated more clearly in what follows.

In this example, the material of which the surface modification layer 10 is made operates like a photoresist of a negative type; i.e., it is selectively removable in the regions not exposed to ultraviolet radiation 11, while, as a result of the cross-linking generated in the exposed regions, the latter remain on the wafer 50. It is evident that, using other types of photoresist, these may be of a positive type. In this case, it is the portions exposed to ultraviolet radiation that are removed by the subsequent development step, whereas the portions not exposed remain on the wafer 50.

The step of exposure is followed by a baking step (typically identified as “post-exposure bake”), on a hot plate, at a temperature ranging between 100° C. and 170° C., in particular 150° C., for a time comprised between 30 s and 600 s, in particular 300 s, in order to complete the cross-linking step.

According to a different embodiment, the step of exposure may be carried out by means of electron-beam lithography. In this case, if an electron beam appropriately oriented is used, the exposure mask 13 is not necessary.

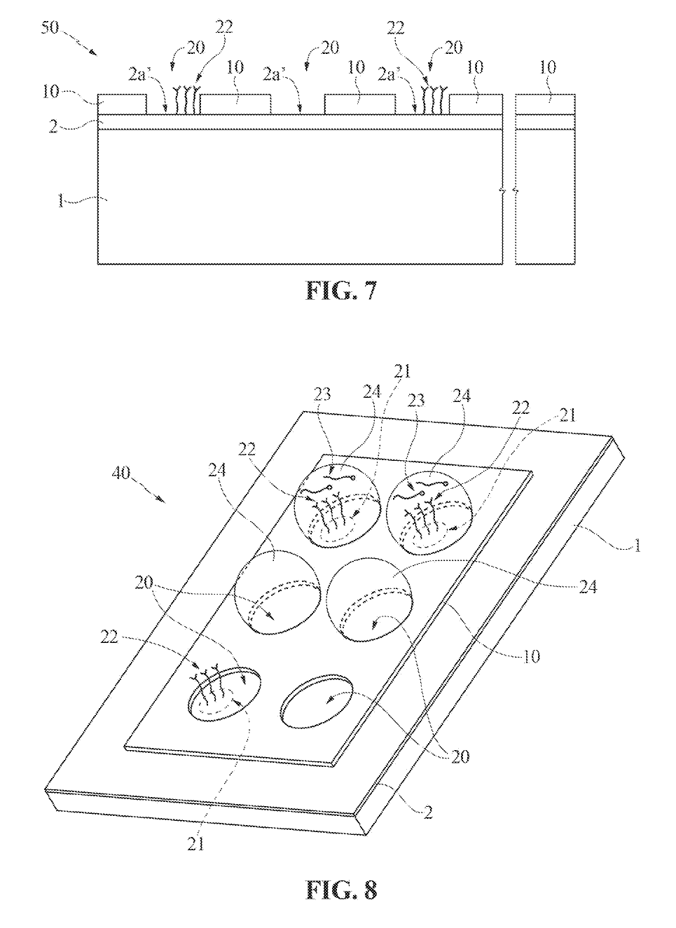

Next (FIG. 7), a step of development of the surface modification layer 10 is carried out, during which the regions of the surface modification layer 10 not exposed to ultraviolet light are selectively removed, whereas the exposed regions remain on the surface 2a of the structural layer 2. The development takes place, for example, in solvent solution; in particular, if the material according to formula (1) is used, the development is carried out in a solution with a PGMEA (propylene glycol monomethyl ether acetate) base. Other materials may require a development in solutions other than solvents, for example aqueous solutions.

A plurality of islands 20 is thus defined formed by openings, which extend right through the surface modification layer 10 and expose respective surface portions 2a′ of the structural layer 2.

If the mask 13 of FIG. 6 is used, the islands 20 have a substantially circular shape (in top plan view, i.e., in the plane defined by the top surface 2a). However, it is evident that said islands 20 may have a shape chosen according to the need, for example oval or polygonal, or some other shape still (generally polygonal), by appropriately shaping the mask 13.

It should be noted that, since a circular or oval shape is without angles, it guarantees a complete wettability of the surface portions 2a′ of the islands 20. Instead, this advantage is absent in the case of an island 20 that has a quadrangular shape, the walls of which form sharp corners.

After the development step, a rinsing step, using solvents (for those materials that are developed with solvent) or water (for materials that can be developed in aqueous solutions), favors cleaning of the islands 20 thus formed, preventing any residue of the surface modification layer 10 that has been removed from remaining on the surface portions 2a′ or on the top surface of the surface modification layer 10, in an undesirable way.

Finally, a final baking step is carried out, at a temperature ranging between 100 and 400° C., in particular 180° C., for a time comprised between 30 min and 480 min, in particular 120 min, and in environment saturated with an inert gas (for example, nitrogen, N₂) in order to stabilize the material and render it permanent.

At this point, the surface modification layer 10 presents hydrophobic properties, both when using static measurements of angle of contact and when using dynamic measurements of angle of contact. In order to guarantee that the islands 20 (where surface modification layer 10 has been removed) maintain an adequate hydrophilicity even after the surface modifications obtained by the previous process steps, a bath in HF or some other wet solution is then carried out, such as to restore the surface conditions of hydrophilicity of the structural layer 2 at the islands 20 without any impact on the hydrophobic properties of the surface modification layer 10.

According to an embodiment, the islands 20 (i.e., the surface portions 2a′ of the structural layer 2) are functionalized via grafting of receptors or the like (in particular, receptor biomolecules).

The functionalization step can be carried out by means of an automated spotting technique of a type in itself known, which substantially envisages the use of a mechanical arm, which automatically picks up the biological material for being deposited (in liquid solution) and with micrometric precision deposits drops of said biological material selectively in the islands 20 to form sensing regions 21. Typically, each of said drops is of a few picolitres, but the drops may be up to 1-5 μl large or larger according to the application and the size of each island 20.

The sensing regions 21 comprise, for example, a given type of receptors 22, such as for instance biomolecules (DNA, RNA, proteins, antigens, antibodies, etc.) or micro-organisms or parts thereof (bacteria, viruses, spores, cells, organelles, etc.) or any chemical element used for detecting an analyte. The receptors 22, provided with specific markers, for example fluorescent markers, are grafted on the surface 2a′. According to alternative embodiments, the receptors 22 may be free in solution instead of being grafted to the device according to the application for which the device is used.

However, solid-phase assays are generally preferred since they enable washing of non-grafted material and hence increase the sensitivity and simplicity of the sensing assays.

By the term “receptors” is here meant any member of a pair or multiple of elements that may bind to one another (“binding pair”) so that the receptor will mate to or react with, and hence detect, its own binding mate (or mates) 23. Hence, “receptors” include traditional receptors, such as protein receptors and ligands, but also any member of a multiplicity of elements that are able to interact or mate, such as for example lectins, carbohydrates, streptavidins, biotins, proteins, substrates, oligonucleotides, nucleic acids, porphyrins, metal ions, antibodies, antigens, and the like.

When these receptors 22 are set in direct contact with a specimen for being analyzed, the presence in said specimen of molecules 23 able to mate or interact with the active receptor 22 activates specific markers, for example fluorescent markers, which, when excited by light radiation at a certain wavelength λₑ emit light radiation of their own having a wavelength λ_{f} different from the wavelength λₑ. The markers are activated (i.e., they emit fluorescent radiation at a wavelength λ_{f}) only when the binding mate (or mates) 23 with which the receptor 22 can bind mates or interacts with the receptor 22.

The phenomenon of fluorescence is particularly useful in research and diagnostic methods that envisage the use of devices obtained using MEMS technology.

There are many different ways to prepare tests that involve optical signals. For instance, a three-component binding assay uses a first antibody grafting to a solid substrate that can bind with an antigen present in a standard solution. Binding with the antigen is then detected with a second antibody, which binds to a different epitope of the same antigen and possesses a fluorescent label attached thereto. Hence, the amount of fluorescence is correlated to the amount of antigens present in the specimen.

Another example implies grafting of an oligonucleotide probe to the substrate (or an oligonucleotide probe free in solution), which is then hybridized with DNA or cDNA or complementary mRNA present in the specimen, and the double-stranded nucleic acid can be detected with an intercalating dye, such as for example ethidium bromide.

In yet another example, two fluorescent markers are brought into strict proximity in the assay, and quenching of a marker is measured in assays based upon fluorescence resonance-energy transfer (FRET).

As further example, binding of heavy metals with fluorophores may also be detected by means of fluorescent dyes. Irrespective of the details of the assays, similar devices may be generically used with optical assays.

The light radiation in assays of the type described may be collected by an appropriate detector, such as for example a photodetector of a CCD (charge-coupled device) type or CMOS type compatible with the wavelength λ_{f} of the light radiation emitted. The variation of light intensity is a function of the number of specific markers activated in the assay, and hence of the number of molecules or biomolecules detected by the assay.

FIG. 8 is a perspective view of a chemical microreactor 40 obtained from dicing of the wafer 50 after the manufacturing step illustrated in FIG. 7.

With reference to FIG. 8, according to an application of the chemical microreactor 40, drops of a fluid, or liquid, 24, which represents the specimen for being analyzed, are selectively deposited on the islands 20, in direct contact with the surface portions 2a′ of the structural layer 2 exposed through the surface modification layer 10. The liquid extends to cover completely or partially said surface portions 2a′ (having good wettability and small angle of contact), but does not cover portions of the surface modification layer 10 that surround the respective surface portions 2a′. In fact, as has been said, the surface modification layer 10 has low wettability and wide angle of contact (it presents, that is, hydrophobic characteristics). In this way, there is a high confinement of the drops of liquid within the islands 20 and reduced hydrophobic interactions (e.g., due to Van der Waals forces) between organic molecules that may be present in the liquid (in the case of biological analyses) and the surface portions 2a′ (which are, instead, hydrophilic).

The chemical microreactor 40 of FIG. 8 can find application in biological-analysis systems or devices, for example systems for PCR (Polymerase Chain Reaction), or generic diagnostic systems based upon fluorescence.

In fact, as is known, the analysis of nucleic acids requires, according to various modalities, preliminary steps of preparation of a specimen of biological material, amplification of the nucleic material contained therein, and hybridization of individual target or reference strands, corresponding to the sequences sought. Hybridization takes place (and the test yields positive results) if the specimen contains strands complementary to the target strands. At the end of the preparatory steps, the specimen is examined to check whether hybridization has occurred (so-called recognition or detection step). The preparatory steps that precede amplification can be carried out separately and use purposely provided instrumentation and reagents.

With reference to FIG. 9, for amplification of the nucleic material and for the recognition or detection step it is possible to use the microreactor 40 of FIG. 8, manufactured as described with reference to FIGS. 1-7. In this case, the microreactor 40 further comprises heaters 41, produced in integrated form at the back of the substrate 1 (i.e., on the surface 1b of the substrate 1), or else fitted into the back of the substrate 1 in a way not shown in detail in the figures. There may moreover be present temperature sensors 42, which are also integrated on the surface 1b of the substrate 1, or else fitted therein.

The microreactor 40 is loaded with drops of liquid 23 which form the biological specimens for being analysed, and is then introduced into a thermocycler 45 for carrying out biochemical analyses. The thermocycler 45, which is known in the prior art, is configured for receiving one or more microreactors 40 mounted on purposely provided boards and in general comprises at least one control unit 46, a cooling device (e.g., a fan) 47, and a detection device 48 including a light source 48a for illuminating the specimen for being analysed with light radiation having a first wavelength and a photodetector 48b for acquiring light radiation having a second wavelength, emitted by the specimen in response to the light radiation used for illuminating the specimen.

The control unit 46 can be connected to the heaters 41 and to the temperature sensors 42 of the microreactor 40 through appropriate connectors and, by exploiting the temperature sensors 42 on board the microreactor 40 itself, controls the heaters 41 and the cooling device 47 for carrying out pre-set thermal cycles.

Once the biochemical processes are completed, the detection device 48, which is typically of an optical type, verifies whether in the specimen processed (i.e., in the respective drop of liquid 23) there are present or not given substances (for example, given nucleotide sequences). Optical detection typically exploits fluorophores, which, during processing of the specimen, bind selectively to the substances for being detected, emitting a characteristic light radiation.

The advantages of the invention according to the present disclosure and of the manufacturing method thereof emerge clearly from the foregoing description.

In particular, according to the present invention, it is possible to control the characteristics of wettability of surfaces with a very high precision, given by the precision made possible by the photolithographic technique used and by the precision enabled by the photo-definable material used for the surface modification layer 10.

Furthermore, the manufacturing steps are considerably simplified in so far as further etching steps are not required after the step of development of the surface modification layer 10. In fact, it is the surface modification layer 10 itself, which, as has been said, is made of photo-definible material, that has the function of forming a hydrophobic surface.

In addition, the embodiment of the surface modification layer 10 described guarantees at the same time thermal resistance, control of the thickness, high patterning resolution and chemical inertia.

Finally, it is clear that modifications and variations may be made to what has been described and illustrated herein, without thereby departing from the sphere of protection of the present invention, as defined in the annexed claims.

For instance, the functionalization step, described with reference to FIG. 7 (i.e., before the step of dicing of the wafer 50 of FIG. 8) can be carried out after the step of dicing of the wafer 50 of FIG. 8.

Furthermore, the surface modification layer 10 can be defined photolithographically to form channels that connect different islands 20 together or else channels that connect one or more islands 20 to respective sections for inlet of liquid for being analyzed, according to the need. Each channel is formed right through the surface modification layer 10, exposing respective surface portions 2a′ of the underlying structural layer 2.

What is claimed is:

1. A microfluidic device, comprising:
a support body having a first surface and a second surface opposite to one another, wherein the first surface is hydrophilic;
a hydrophobic surface modification layer extending over the first surface of the support body,
wherein the surface modification layer has at least one opening extending completely through the surface modification layer, thus exposing a portion of the first surface, and
wherein the surface modification layer is made of a photodefinible material selected from the group consisting of: an epoxy resin, a polyamide, and a photocurable siloxane-based polymer; and
at least one sensing region housed in each opening comprising one or more receptors which are configured to bond with respective one or more binding mates.

2. The microfluidic device of claim 1, wherein the photodefinable material has a recurrent unit of the type 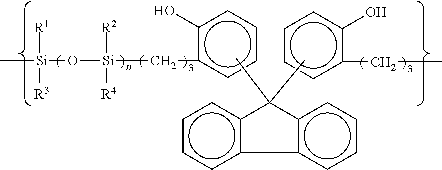
where: R¹ and R⁴ are each a C₁-C₈ alkyl, and n is an integer between 1 and 1000.

3. The microfluidic device according to claim 1, wherein said interface modification layer has a thickness from 1 to 500 μm.

4. The microfluidic device according to claim 1, wherein said opening has a shape, in top plan view, that is one of substantially circular or oval.

5. The microfluidic device according to claim 1, wherein said support body is made of a material selected from the group consisting of: silicon oxide, silicon nitride, silicon, silicon carbide, and hydrophilic metal.

6. The microfluidic device according to claim 1, wherein said support body includes a substrate and a structural layer extending over the substrate, said structural layer defining said first surface and being made of a material selected from the group consisting of: silicon oxide, silicon nitride, silicon, silicon carbide, and hydrophilic metal.

7. The microfluidic device according to claim 1, wherein said receptors include probe molecules grafted to the first surface of the support body, said binding mates being target molecules to be detected.

8. The microfluidic device according to claim 7, wherein said probe molecules are labeled with marker molecules that, when activated and excited by a first light radiation having a first wavelength, are configured to emit a second light radiation having a second wavelength.

9. The microfluidic device according to claim 1, wherein the device comprises one of: a chemical microreactor and a disposable device for biological analyses.

10. A method for manufacturing a microfluidic device, comprising:
forming a hydrophobic surface modification layer on a first surface of a support body having said first surface and a second surface opposite thereto, wherein the first surface is hydrophilic,
wherein the surface modification layer is made of a photodefinible material selected from the group consisting of: an epoxy resin, a polyamide, and a photocurable siloxane-based polymer;
forming at least one opening through the surface modification layer to expose a portion of the first surface; and
functionalizing said portion of the first surface to form at least one sensing region comprising one or more receptors which are configured to bond with respective one or more binding mates.

11. The method of claim 10, wherein the photodefinable material has a recurrent unit of the type 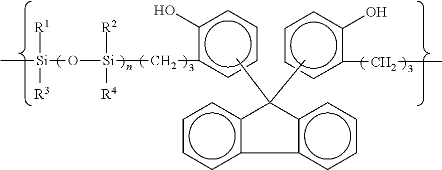
where: R¹ and R⁴ are each a C₁-C₈ alkyl, and n is an integer between 1 and 1000.

12. The method according to claim 10, wherein forming the surface modification layer comprises: laminating a dry film.

13. The method according to claim 10, wherein forming the surface modification layer comprises: carrying out a step of spin coating.

14. The method according to claim 10, wherein forming the surface modification layer comprises forming the surface modification layer with a thickness comprised from 1 to 500 μm.

15. The method according to 10, wherein forming said opening comprises:
removing selective portions of the surface modification layer by means of a process of photolithography; and
developing the surface modification layer.

16. The method according to claim 10, further comprising, after removing selective portions of the surface modification layer, carrying out a bath in one of HF or wet solution including HF of the portion of the first surface exposed through said opening.

17. The method according to claim 10, wherein the support body comprises a substrate of a material selected from the group consisting of: silicon oxide, silicon nitride, silicon, silicon carbide, and hydrophilic metal.

18. The method according to claim 10, further comprising forming said support body by:
providing a support substrate; and
forming on said support substrate a structural layer defining said first surface,
wherein the structural layer is made of a material selected from the group consisting of: silicon oxide, silicon nitride, silicon, silicon carbide, and hydrophilic metal.

19. The method according to claim 10, wherein functionalizing comprises grafting probe molecules to the portion of the first surface of the support body.

20. The method according to claim 10, further comprising forming at least one of a chemical microreactor and a disposable device for biological analyses from the microfluidic device.
